(19) United States
(12) Patent Application Publication
(10) Pub. No.: US 2025/0343065 A1
(43) Pub. Date: Nov. 6, 2025

(54) METHOD FOR FORMING PACKAGE STRUCTURE

(71) Applicant: Taiwan Semiconductor Manufacturing Company, Ltd., Hsinchu (TW)

(72) Inventors: Ju-Pin SUN, Hsinchu City (TW); Amram EITAN, Hsinchu County (TW); Chin-Fu KAO, Taipei City (TW); Kai-Hsiang YANG, Hsinchu County (TW); Shu-Cheng LIN, Taichung City (TW)

(21) Appl. No.: 19/271,938

(22) Filed: Jul. 17, 2025

Related U.S. Application Data
(63) Continuation of application No. 18/429,565, filed on Feb. 1, 2024.

(51) Int. Cl. H01L 21/683; H01L 21/67; H01L 23/00

(52) U.S. Cl. CPC H01L 21/6838; H01L 21/67092; H01L 24/80; H01L 2224/80895; H01L 2224/80896

(57) ABSTRACT

A method for forming a package structure is provided. The method includes deforming an upper package component on a surface of a bonding head by holding the upper package component with a plurality of vacuum holes along opposite edges of the bonding head, and a peak of the surface is located between the opposite edges of the bonding head. The method includes aligning the upper package component with a lower package component. The method includes pressing the upper package component onto the lower package component until an edge of the upper package component contacts an edge of the lower package component. The method includes releasing the upper package component from the bonding head.

### CROSS REFERENCE TO RELATED APPLICATIONS

This application is a continuation of pending U.S. patent application Ser. No. 18/429,565, filed Feb. 1, 2024, the entirety of which is incorporated by reference herein.

### BACKGROUND

Three dimensional integrated circuit (3D IC) technology is emerging as a new scheme for IC fabrication and system integration, to combine mixed technologies for achieving high-density integration with small form factor, high performance and low power consumption. In addition, 3D IC is a promising solution to the limitations of Moore's law. Vertical interconnection often utilizes a 3D integration structure, chip to chip (C2C) bonding, chip to wafer (C2W) bonding, wafer to wafer (W2W) bonding, package to substrate bonding, or the like. Although existing processing apparatuses for such bonding have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIG. 1 illustrates a schematic view of a processing apparatus in accordance with some embodiments.

FIG. 2 illustrates a schematic view of a bonding head in accordance with some embodiments.

FIG. 3 illustrates a cross-sectional view of the bonding head in accordance with some embodiments.

FIG. 4 illustrates a plan view of the bonding head and the second package component in accordance with some embodiments.

FIGS. 5A through 5D illustrate cross-sectional views of intermediate steps of a method for forming a package structure in accordance with some embodiments.

FIG. 6A illustrates a schematic view of the bonding head in accordance with some embodiments.

FIGS. 6B and 6C illustrate cross-sectional views of the bonding head shown in FIG. 6A.

FIG. 7 illustrates a schematic view of the bonding head in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of processing apparatus and method for forming package structures are provided. The processing apparatus includes a bonding head with a non-planar bottom surface (for example, arc-shaped). Accordingly, the package component attached to the bonding head may be deformed to conform to the bottom surface of the bonding head. During the bonding process, the lower contact portion (for example, center portion) of the package component contacts the underlying component first, and then the edges of the package component are in contact with the underlying component. In this way, the voids or gaps between the package component and the underlying component may be minimized, thereby improving the quality and reliability of the package structure to be formed.

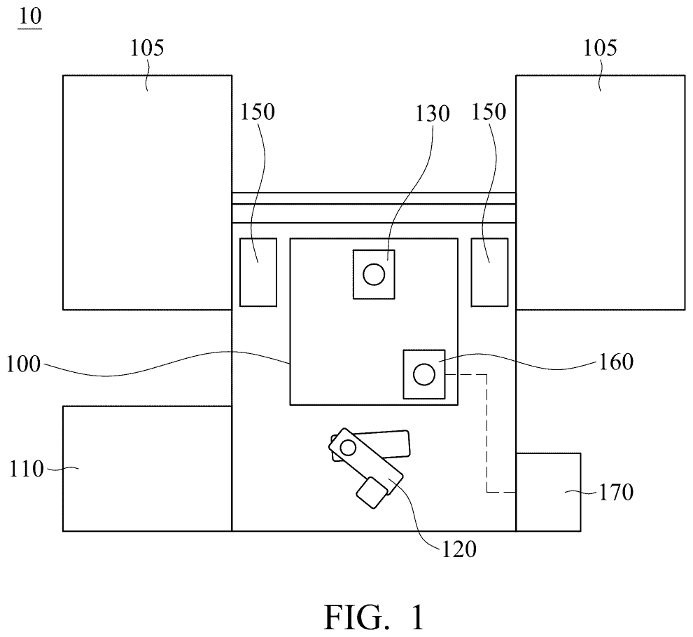

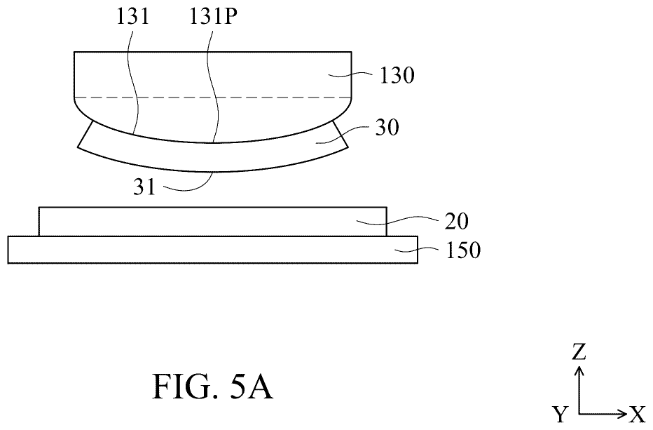

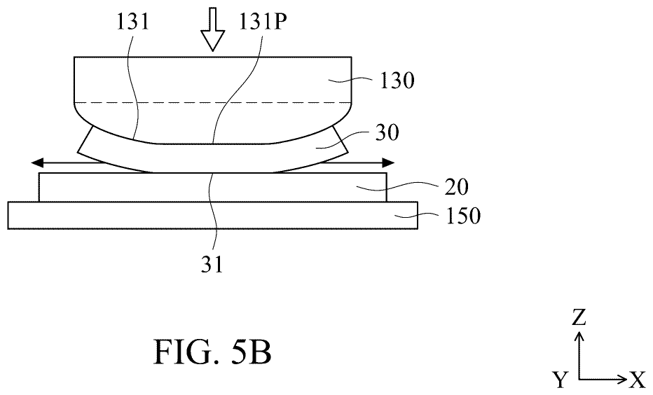

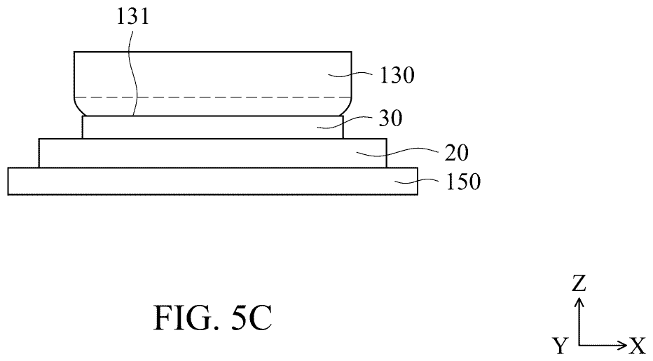

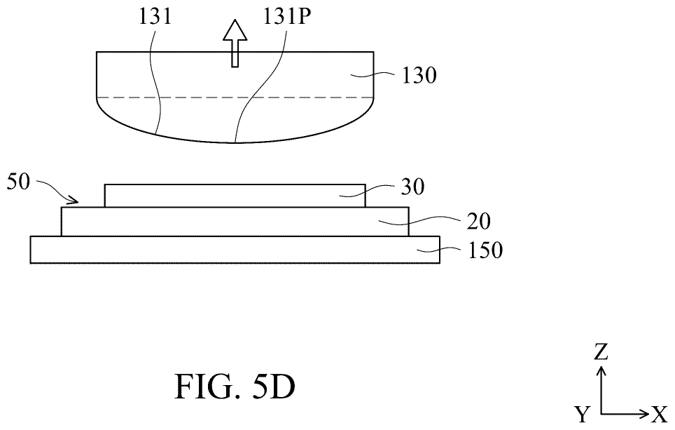

FIG. 1 illustrates a schematic view of a processing apparatus 10 in accordance with some embodiments. In some embodiments, the processing apparatus 10 is configured to form a package structure, for example, performing a bonding process to bond a first package component 20 and a second package component 30 (for example, as shown in FIGS. 5A-5D). In some embodiments, the processing apparatus 10 can be used for a chip to wafer (C2W) bonding process. During the bonding process, electrical connectors at a bonding surface of a first package component 20 (e.g., a device wafer or an interposer wafer) are bonded to electrical connectors at a bonding surface of a second package component 30 (e.g., a semiconductor chip). In some embodiments, the first package component 20 and the second package component 30 are bonded via dielectric-to-dielectric bonding. However, the present disclosure is not limited thereto. For example, the first package component 20 and the second package component 30 may be bonded via fusion bonding or hybrid bonding. In some embodiments, the first package component 20 and the second package component 30 are bonded via dielectric-to-dielectric bonding and metal-to-metal bonding.

In some embodiments, the processing apparatus 10 includes a processing chamber 100, a component feeding module 110, and a component transfer module 120. The processing chamber 100 is configured to performing the bonding process therein. The component feeding module 110 is configured to supply and/or store second package components 30, and the component transfer module 120 is configured to transfer the second package components 30 from the component feeding module 110 to the processing chamber 100. For example, in some embodiments, the component transfer module 120 is a robotic arm or any other suitable transfer device that may move smoothly along any of a horizontal, vertical, and/or rotational direction so as to transfer the second package components 30 between the component feeding module 110 and the processing chamber 100.

In some embodiments, the processing apparatus 10 further includes a bonding head 130 that is configured to receive the second package components 30 from the component transfer module 120. The detail structure of the bonding head 130 will be discussed in the following description. In some embodiments, the bonding head 130 introduce a vacuum pressure to hold the second package components 30 thereon. Similarly, the bonding head 130 may move smoothly along any of a horizontal, vertical, and/or rotational direction so as to hold and move the second package components 30 in the processing chamber 100.

In some embodiments, the processing apparatus 10 further includes a heating module 160 disposed in the processing chamber 100. The heating module 160 is configured to heat the second package components 30 during the transfer of the second package components 30. In some embodiments, the heating module 160 heats the second package components 30 after the second package components 30 are transferred into the processing chamber 100. In some embodiments, the heating module 160 emits radiation towards the second package components 30. In some embodiments, the heating module 160 is an infrared (IR) lamp module and emits infrared light with a wavelength in a range from about 760 nm to about 1 mm. In some embodiments, the heating module 160 has a heating area corresponding to a surface area of single second package component 30. The processing apparatus 10 further includes a cooling module 170 connected to the heating module 160 for controlling the temperature of the heating module 160 so as to further control the temperature of the second package components 30. The arrangement of the cooling module 170 helps to reduce the possibility that the heating module 160 overheats and damages the second package components 30.

In some embodiments, the processing apparatus 10 further includes a plurality of component storage modules 105 and a plurality of chuck tables 150. The component storage modules 105 are configured to supply and/or store first package components 20. In some embodiments, the processing apparatus 10 further includes a carrier (not shown) to transfer the first package components 20 from the component storage modules 105 to the chuck table 150. The chuck tables 150 are configured to hold the first package components 20 for subsequent bonding process. In some embodiments, the chuck tables 150 with the first package components 20 held thereon are transferred into the processing chamber 100 for the subsequent bonding process. Although multiple component storage modules 105 and chuck tables 150 shown in the present embodiment, the number of the component storage modules 105 and chuck tables 150 is not limited thereto and adjustable by those skilled in the art. In some embodiments, the chuck tables 150 are made of an insulating material (e.g., a ceramic material or a glass material), so as to avoid undesired absorption of induction power.

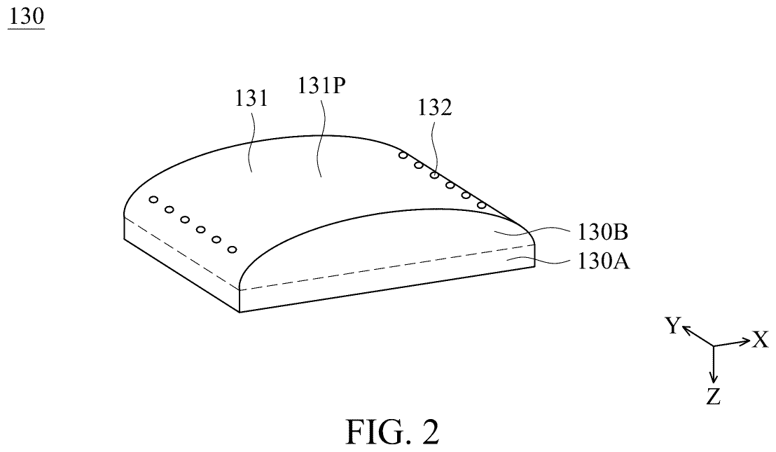

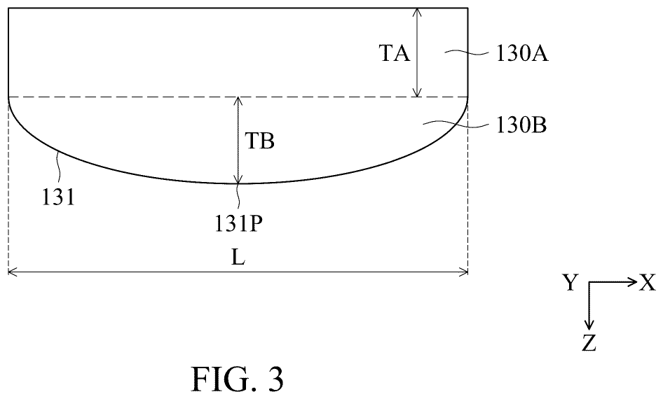

FIG. 2 illustrates a schematic view of the bonding head 130 in accordance with some embodiments. FIG. 3 illustrates a cross-sectional view of the bonding head 130 in accordance with some embodiments. In some embodiments, the bonding head 130 has a bottom surface 131 that is non-planar (for example, curved) and it faces the top surface of the chuck table 150 (referring to FIGS. 5A-5D, for example). In some embodiments, the shape of the bottom surface 131 is arc-shaped. In the embodiments that the bottom surface 131 is curved, a peak 131P may be formed on the bottom surface 131. The peak 131P of the bottom surface 131 may be defined as a region that is closest to the underlying chuck table 150. That is to say, the bottom surface 131 of the bonding head 130 is a non-planar surface and therefore would not be parallel to the top surface of the chuck table 150. The effect of the non-planar bottom surface 131 of the bonding head 130 will be further discussed in accompany with FIGS. 5A-5D as below.

In some embodiments, a cross-sectional area of the bonding head 130 varies along a direction (for example, the X axis) that is substantially parallel to the lengthwise side of the bonding head 130 varies, and the cross-sectional area of the bonding head 130 may be measured on the Y-Z planes, for example. In particular, the maximum cross-sectional area of the bonding head 130 may exist on a plane that passes through the peak 131P, and the minimum cross-sectional area of the bonding head 130 may exist on edges of the bonding head 130.

In some embodiments, the bonding head 130 includes a plurality of vacuum holes 132 that are formed on the bottom surface 131. To be more specific, the vacuum holes 132 may each communicates with a vacuum device (not shown) that is inherently disposed in or out of the bonding head 130. It should be noted that more than one vacuum devices may be disposed and they could operate independently from each other. For example, the vacuum pressure supplied by the vacuum devices can be different to provide sufficient force to hold the second package component 30. Although the detailed arrangement of the vacuum devices is not elaborated herein, any suitable configuration of the vacuum devices should be contemplated within the scope of the present disclosure.

In some embodiments, the bonding head 130 may be divided into a first portion 130A and a second portion 130B that is connected to the first portion 130A. For example, the first portion 130A may be referred to as the portion in which the length of the bonding head 130 is constant. The second portion 130B may be referred to as the portion in which the length of the bonding head 130 varied, for example, gradually decreased from the center of the bonding head 130 to edges of the bonding head 130. In some embodiments, the length of the first portion 130A may be measured in a direction that is parallel to the X axis and defined as the length L, and the maximum width of the second portion 130B may be shorter than the length L.

In addition, the first portion 130A of the bonding head 130 has a first thickness TA, and the second portion 130B of the bonding head 130 has a second thickness TB. It should be appreciated that the first thickness TA and the second thickness TB may be measured in a direction that is substantially parallel to the Z axis. However, the present disclosure is not limited thereto. For example, the second thickness TB may be measured at the peak 131P. In some embodiments, the first thickness TA is greater than the second thickness TB. As a result, the first portion 130A may provide sufficient support for the second portion 130B, which helps to flatten the second portion 130B of the bonding head 130 so as to bond the second package component 30 onto the first package component 20. It should be noted that if the first thickness TA is insufficient (for example, too thin), the second portion 130B of the bonding head 130 might not be deformed or flattened to arrange the second package component 30 as desired. In some embodiments, the ratio of to the second thickness TB to the length Lis less than about 2%. Accordingly, the second package component 30 may be deformed to conform to the bottom surface 131 of the bonding head 130. However, the present disclosure is not limited thereto.

In some embodiments, the bonding head 130 may include a resilient material. For example, the resilient material includes polymer, rubber, silicone, other suitable resilient material, or a combination thereof. However, the present disclosure is not limited thereto. In some embodiments, the Shore A hardness of the resilient material is within a range of about 10 to about 90. It should be noted that if the Shore A hardness of the resilient material is too high, the bonding head 130 would not be deformable enough to flatten the second package component 30. Otherwise, if the Shore A hardness of the resilient material is too low, the bonding head 130 would not have sufficient structural strength to hold the second package component 30.

For example, the resilient material may be tested under a standard practice (such as ASTM D1349-99). To be more specific, the resilient material may be tested under about 100° C. for approximately 22 hours. After the testing, the compressed percentage (measured in single dimension) of the resilient material may be less than about 50%. As a result, the bonding head 130 may be sustainable for multiple bonding processes. In some embodiments, the bonding head 130 may be made as one-piece. However, the present disclosure is not limited thereto. In some embodiments, the bonding head 130 may be formed by combining different portions that are made separately.

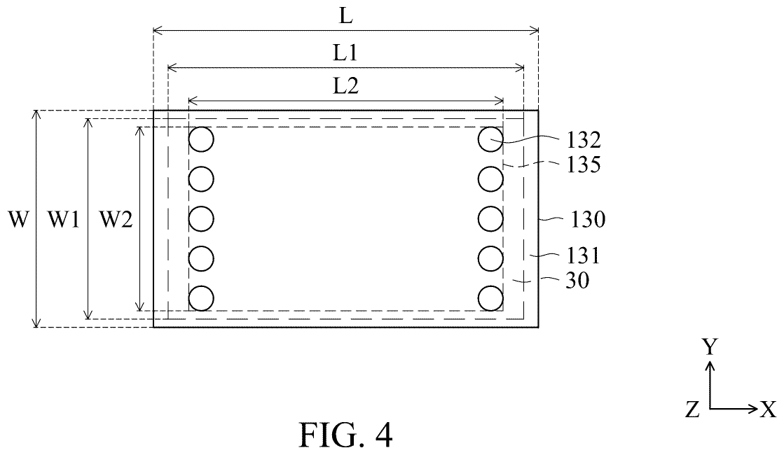

FIG. 4 illustrates a plan view of the bonding head 130 and the second package component 30 in accordance with some embodiments. It should be noted that in order to illustrate the vacuum holes 132 on the bottom surface 131 of the bonding head 130, the second package component 30 is illustrated in dotted lines. As shown in FIG. 4, the bonding head 130 includes a suction region 135 in which the vacuum holes 132 are distributed. For example, the vacuum holes 132 are arranged along the widthwise sides of the bonding head 130. However, the present disclosure is not limited thereto. In some embodiments, the vacuum holes 132 are arranged along each side of the bonding head 130. In some embodiments, the vacuum holes 132 may be formed parallel to an edge of the second package component 30, and therefore the vacuum holes 132 may be arranged linearly (for example, substantially parallel to the Y direction). It should be noted that although five vacuum holes 132 are formed on each side of the bonding head 130, any suitable configuration (including amount, location, etc.) of the vacuum holes 132 is included within the scope of the present disclosure.

In some embodiments, the bonding head 130 has a length L and a width W, the second package component 30 has a length L1 and a width W1, and the suction region 135 has a length L2 and a width W2. It should be appreciated that the lengths L, L1 and L2 and may be measured in a direction that is substantially parallel to the X axis, and the widths W, W1 and W2 and may be measured in a direction that is substantially parallel to the Y axis. However, the present disclosure is not limited thereto.

In some embodiments, the cross-sectional area of the bonding head 130 is greater than the cross-sectional area of the second package component 30 on a horizontal plane (such as the X-Y plane). That is, the length L of the bonding head 130 is greater than the length L1 of the second package component 30, and the width W of the bonding head 130 is greater than the width W1 of the second package component 30. Accordingly, the bonding head 130 may fully cover the second package component 30, reducing the risk of the second package component 30 accidentally detached from the bonding head 130.

In some embodiments, the length L1 of the second package component 30 is greater than the length L2 of the suction region 135 where the vacuum holes 132 are distributed. The width W1 of the second package component 30 is greater than the width W2 of the suction region 135. In this way, the second package component 30 may be firmly held by the bonding head 130. In some embodiments, the length L2 of the suction region 135 is greater than about 0.7 times the length L1 of the second package component 30. The width W2 of the suction region 135 is greater than about 0.7 times the width W1 of the second package component 30. As a result, the suction region 135 (the vacuum holes 132) are capable of providing sufficient suction force to hold the second package component 30. It should be noted that the deformation of the second package component 30 depends upon the thickness of the second package component 30 and the suction force from the suction region 135. Therefore, the suction force from the suction region 135 may be adjustable to provide sufficient suction force for holding various second package components 30.

In some embodiments, the shapes of the bonding head 130, the second package component 30, and the suction region 135 on the horizontal plane (for example, the X-Y plane) may be rectangular. However, the present disclosure is not limited thereto. Any suitable shape and arrangement of the bonding head 130, the second package component 30, and the suction region 135 are acceptable in the present disclosure.

FIGS. 5A through 5D illustrate cross-sectional views of intermediate steps of a method for forming a package structure 50 in accordance with some embodiments. It should be noted that the package structure 50 may be formed in the processing chamber 100 by bonding the second package component 30 onto the first package component 20. However, the present disclosure is not limited thereto. The steps shown in FIG. 5A through 5D may be performed in the processing chamber 100 or any other suitable place.

As shown in FIG. 5A, a first package component 20 is positioned on a chuck table 150 so that the chuck table 150 holds the first package component 20 for subsequent bonding process. In some embodiments, the first package component 20 may be formed of a semiconductor material, such as silicon, silicon germanium, silicon carbide, gallium arsenide, or other commonly used semiconductor materials. In some embodiments, the first package component 20 is a device wafer and includes at least one device, which may be passive devices (such as resistors, capacitors, and inductors) or active devices (such as transistors and diodes). However, the present disclosure is not limited thereto.

In some embodiments, the first package component 20 has a plurality of die regions (not individually shown), which could be singulated from the device wafer to form semiconductor chips as respectively similar to the second package component 30 described below. In these embodiments, the first package component 20 has a size much greater than a size of the second package component 30. In some embodiments, the die regions could remain unsingulated in the device wafer. In these embodiments, the first package component 20 has a size substantially corresponding to a size of the second package component 30.

In some embodiments, the first package component 20 is formed of a dielectric material, such as glass, aluminum oxide, aluminum nitride, the like, or a combination thereof. The first package component 20 is free from passive devices (such as resistors, capacitors, and inductors) or active devices (such as transistors and diodes). In some embodiments, the first package component 20 is an interposer wafer. In other words, the second package component 30 may be bonded to the interposer wafer, rather than being bonded to the device wafer as described above. The interposer wafer is sandwiched between package components (e.g., the semiconductor chip as described above and a package substrate (not shown)) in a finalized package structure (which may be a chip-on-wafer-on-substrate (CoWoS) structure), and configured to interconnect these vertically separated package components. Although the first package component 20 is introduced as above, the present disclosure is not limited thereto. It should be noted that the first package component 20 may be any semiconductor structure as desired.

In addition, a second package component 30 is attached onto the non-planar bottom surface 131 (i.e., the curved surface) of the bonding head 130 so that the bonding head 130 holds the second package component 30. In some embodiments, the second package component 30 is a semiconductor die. For example, the semiconductor die may include a logic chip, a memory chip, a sensor chip, a digital chip, an analog chip, a wireless and radio frequency chip, a voltage regulator chip, an application-specific integrated chip (ASIC) or any other type of semiconductor chip. In some embodiments, the second package component 30 is attracted to and firmly held by the bonding head 130 via a suction force. The suction force may be introduced via the vacuum holes 132 (referring to FIG. 4, for example) on the bottom surface 131 of the bonding head 130. As a result, the second package component 30 may be deformed to conform to the profile (for example, arc-shaped profile) of the bottom surface 131 of the bonding head 130. Since the second package component 30 is deformed, a lower contact portion 31 is formed corresponding to the peak 131P of the bottom surface 131. For example, the lower contact portion 31 of the second package component 30 may be located directly below the peak 131P of the bottom surface 131. The lower contact portion 31 of the second package component 30 may be defined as the portion that is closest to the underlying chuck table 150.

Next, as shown in FIG. 5B, the bonding head 130 is moved to contact the lower contact portion 31 of the second package component 30 with the first package component 20. In some embodiments, the bonding head 130 is moved vertically (for example, downwards) towards the chuck table 150 and the first package component 20. After the lower contact portion 31 of the second package component 30 is in contact with the first package component 20, the bonding head 130 is continuously moved in the vertical direction (which is substantially parallel to the Z axis) until the edges of the second package component 30 also contact the first package component 20, as shown in FIG. 5C. In this way, the second package component 30 contacts the first package component 20 from the center to the edges, which helps to bump the air or gas off the space between the second package component 30 and the first package component 20. Accordingly, the voids or gaps between the first package component 20 and the second package component 30 may be minimized, improving the quality and reliability of the package structure 50 to be formed.

Then, as shown in FIG. 5C, the second package component 30 is flattened on the bottom surface 131 of the bonding head 130 after the lower contact portion 31 of the second package component 30 contacts the first package component 20. To be more specific, a portion of the bottom surface 131 (for example, the portion directly over the second package component 30) of the bonding head 130 is flattened while the bonding head 130 is moved downwards. Since the bonding head 130 is made of a resilient (i.e., deformable) material, the deformation of the bonding head 130 would not damage the second package component 30 which is held on the bonding head 130. In addition, the deformation of the bonding head 130 may ensure the second package component 30 is flattened and fully contacts the first package component 20. After that, the suction force for holding the second package component 30 may be relieved to release the second package component 30 from the bonding head 130 because the second package component 30 has already been disposed over the first package component 20.

In some embodiments, the bonding process between the first package component 20 and the second package component 30 may be performed after the suction force for holding the second package component 30 is relieved. However, the present disclosure is not limited thereto. In some embodiments, the bonding process between the first package component 20 and the second package component 30 is performed when the suction force for holding the second package component 30 still exists.

For example, the bonding process between the first package component 20 and the second package component 30 includes using the chuck table 150 to heat the first package component 20 so as to bond the first package component 20 to the second package component 30. However, the present disclosure is not limited thereto. In some embodiments, the bonding process between the first package component 20 and the second package component 30 includes adhering the second package component 30 onto the first package component 20 using an adhesive (not shown).

Afterwards, as shown in FIG. 5D, the bonding head 130 is away from the second package component 30 after the second package component 30 is disposed over the first package component 20. In some embodiments, the bonding head 130 leaves from the second package component 30 after the second package component 30 is bonded to the first package component 20. Since the bonding head 130 is made of resilient (i.e., deformable) material, the bonding head 130 may bounce back to have a curved bottom surface 131 for subsequent bonding process.

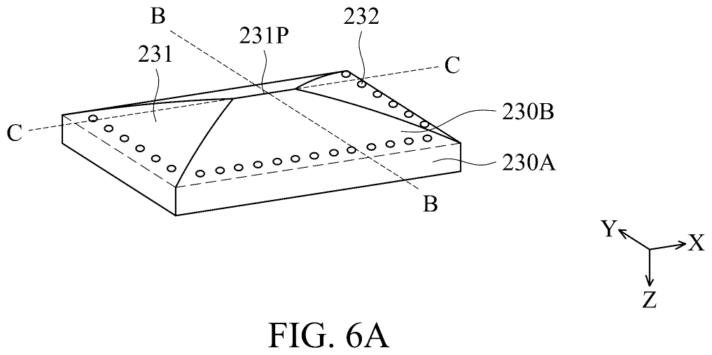

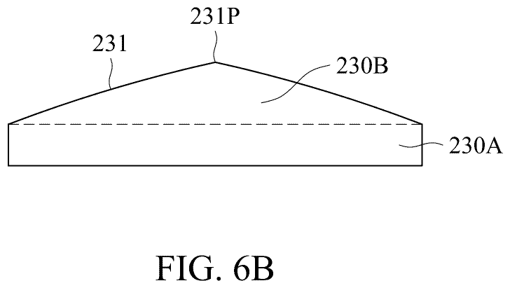

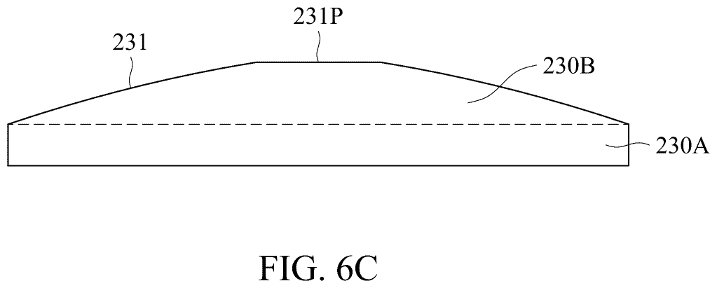

FIG. 6A illustrates a schematic view of the bonding head 230 in accordance with some embodiments. It should be noted that the bonding head 230 may include elements or portions that are the same or similar to those of the bonding head 130 shown in FIGS. 2-4. These elements or portions will be denoted as similar numerals and may not be discussed in detail as follows. As shown in FIG. 6A, the bonding head 230 includes a plurality of vacuum holes 232 that are formed on the bottom surface 231, and the bonding head 230 may be divided into a first portion 230A and a second portion 230B that is connected to the first portion 230A. For example, the first portion 230A may be referred to as the portion in which the length of the bonding head 230 is constant. The second portion 230B may be referred to as the portion in which the length of the bonding head 230 is gradually decreased from the first portion 230A.

The difference between the bonding heads 130 and 230 is that the shape of the bottom surface 231 is dome-shaped or roof-shaped. In some embodiments, the peak 231P may be located at the center of the bottom surface 231 and protrude over each edge of the bottom surface 231. In some embodiments, the vacuum holes 232 may be arranged on each side of the bottom surface 231, and be closer to the edges of the bottom surface 231 than the peak 231P. However, the present disclosure is not limited thereto. In some embodiments, the peak 231P may be offset from the center of the bottom surface 231.

FIGS. 6B and 6C illustrate cross-sectional views of the bonding head 230 shown in FIG. 6A. It should be noted that FIG. 6B may be illustrated along the line B-B shown in FIG. 6A, and FIG. 6C may be illustrated along the line C-C shown in FIG. 6A. However, the present disclosure is not limited thereto. As shown in FIGS. 6B and 6C, the bottom surface 231 is inclined (i.e., not parallel to) relative to the horizontal plane (for example, the X-Y plane) on opposite sides of the peak 231P, and therefore the bottom surface 231 is a non-planar plane. In some embodiments, the peak 231P may extend linearly. However, the present disclosure is not limited thereto.

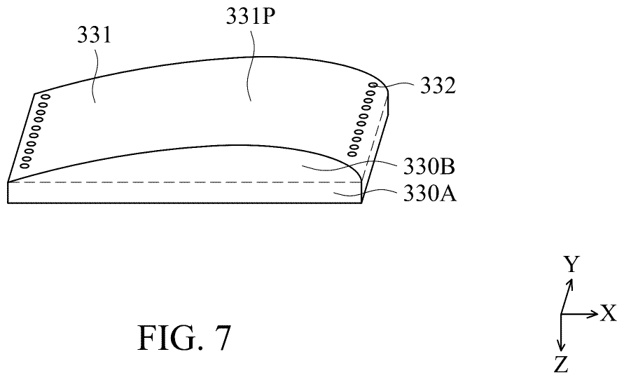

FIG. 7 illustrates a schematic view of the bonding head 330 in accordance with some embodiments. It should be noted that the bonding head 330 may include elements or portions that are the same or similar to those of the bonding head 130 shown in FIGS. 2-4. These elements or portions will be denoted as similar numerals and may not be discussed in detail as follows. As shown in FIG. 7, the bonding head 330 includes a plurality of vacuum holes 332 that are formed on the bottom surface 331, and the bonding head 330 may be divided into a first portion 330A and a second portion 330B that is connected to the first portion 330A. For example, the first portion 330A may be referred to as the portion in which the length of the bonding head 330 is constant. The second portion 330B may be referred to as the portion in which the length of the bonding head 330 is gradually decreased.

The difference between the bonding heads 130 and 330 is that the peak 331P may be offset from the center of the bottom surface 331. That is, the bonding head 330 may be non-symmetric. Such feature may help to hold various second package component 30 since some regions of the second package component 30 may be more or less bendable. The peak 331P may be located to correspond the more bendable region of the second package component 30, thereby facilitating to hold the second package component 30 on the bottom surface 331 of the bonding head 330.

Embodiments of processing apparatus and method for forming package structures are provided. The processing apparatus includes a bonding head with a non-planar (for example, curved) bottom surface. Accordingly, the package component attached to the bonding head may be deformed to a curved-shape. During the bonding process, the lower contact portion of the package component contacts the underlying component first, and then the edges of the package component are in contact with the underlying component. In this way, the voids or gaps between the package component and the underlying component may be minimized, thereby improving the quality and reliability of the package structure to be formed. In addition, the profile of the bottom surface of the bonding head may be variable, so as to correspond to different package component and improve the quality and reliability of the package structure.

In some embodiments, a method for forming a package structure is provided. The method includes deforming an upper package component on a surface of a bonding head by holding the upper package component with a plurality of vacuum holes along opposite edges of the bonding head, and a peak of the surface is located between the opposite edges of the bonding head. The method includes aligning the upper package component with a lower package component. The method includes pressing the upper package component onto the lower package component until an edge of the upper package component contacts an edge of the lower package component. The method includes releasing the upper package component from the bonding head.

In some embodiments, a method for forming a package structure is provided. The method includes vacuuming a package component on a non-planar bottom surface of a bonding head. The method includes moving the bonding head to contact the package component with a target. The method includes flattening the non-planar bottom surface of the bonding head after the package component contacts the target. The method includes releasing the package component from the bonding head after an edge of the package component is bonded to the target.

In some embodiments, a method for forming a package structure is provided. The method includes holding a package component on a bottom surface of a bonding head, wherein the bottom surface has a rectangular profile in a plan view, and has a non-linear profile in a cross-sectional view. The method includes sequentially pressing the package component from a middle region to an edge of the package component. The method includes bonding the package component to form the package structure. The method includes releasing the package component from the bonding head from the edge to the middle region of the package component.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a package structure, comprising:
deforming an upper package component on a surface of a bonding head by holding the upper package component with a plurality of vacuum holes along opposite edges of the bonding head, wherein a peak of the surface is located between the opposite edges of the bonding head;
aligning the upper package component with a lower package component;
pressing the upper package component onto the lower package component until an edge of the upper package component contacts an edge of the lower package component; and
releasing the upper package component from the bonding head.

2. The method as claimed in claim 1, wherein pressing the upper package component onto the lower package component further comprises:
contacting a center portion of the upper package component to the lower package component prior to contacting the edge of the lower package component.

3. The method as claimed in claim 1, wherein deforming the upper package component on the surface of the bonding head comprises deforming the upper package component as an arc-shaped profile along a lengthwise side of the upper package component.

4. The method as claimed in claim 1, wherein the peak of the surface of the bonding head is offset from a center of the surface of the bonding head.

5. The method as claimed in claim 1, further comprising:
deforming the bonding head while pressing the upper package component onto the lower package component.

6. The method as claimed in claim 1, wherein the bonding head comprises a resilient material with a Shore A hardness within a range of about 10 to about 90.

7. A method for forming a package structure, comprising:
vacuuming a package component on a non-planar bottom surface of a bonding head;
moving the bonding head to contact the package component with a target;
flattening the non-planar bottom surface of the bonding head after the package component contacts the target; and
releasing the package component from the bonding head after an edge of the package component is bonded to the target.

8. The method as claimed in claim 7, wherein vacuuming the package component on the non-planar bottom surface of the bonding head comprises:
introducing a suction force via a plurality of vacuum holes in a suction region of the bonding head, wherein a length of the package component is greater than a length of the suction region, and the length of the suction region is greater than or equal to about 0.7 times the length of the package component.

9. The method as claimed in claim 8, wherein the vacuum holes are symmetrically distributed across the suction region of the bonding head.

10. The method as claimed in claim 7, wherein a shape of the non-planar bottom surface of the bonding head is arc-shaped, roof-shaped or dome-shaped.

11. The method as claimed in claim 7, wherein flattening the non-planar bottom surface of the bonding head comprises:
abutting a peak of the non-planar bottom surface to the target via the package component.

12. The method s as claimed in claim 7, wherein flattening the non-planar bottom surface of the bonding head comprises:
bumping off a gas in the space between the edge of the package component and the target.

13. The method as claimed in claim 7, wherein releasing the package component from the bonding head comprises:
restoring the non-planar bottom surface of the bonding head.

14. A method for forming a package structure, comprising:
holding a package component on a bottom surface of a bonding head, wherein the bottom surface has a rectangular profile in a plan view, and has a non-linear profile in a cross-sectional view;
sequentially pressing the package component from a middle region to an edge of the package component;
bonding the package component to form the package structure; and
releasing the package component from the bonding head from the edge to the middle region of the package component.

15. The method as claimed in claim 14, wherein holding the package component on the bottom surface of the bonding head comprises:
introducing a suction force via a plurality of vacuum holes on the bottom surface of the bonding head.

16. The method as claimed in claim 14, wherein holding the package component on the bottom surface of the bonding head comprises:
deforming the package component to conform to a profile of the bottom surface of the bonding head.

17. The method as claimed in claim 14, wherein pressing the package component further comprises:
flattening the package component over a base of the package structure.

18. The method as claimed in claim 17, wherein flattening the package component further comprises:
flattening a portion of the bottom surface of the bonding head over the base of the package structure.

19. The method as claimed in claim 18, wherein flattening the portion of the bottom surface of the bonding head further comprises:
pressing a peak of the bottom surface using the base of the package structure.

20. The method as claimed in claim 19, wherein the peak of the bottom surface is offset from a center of the bottom surface.
